(19) United States
(12) Patent Application Publication
(10) Pub. No.: US 2011/0075079 A1
(43) Pub. Date: Mar. 31, 2011

(54) IMAGE DISPLAY APPARATUS

(75) Inventors: Noriyuki Shikina, Ichihara-shi (JP); Ryuichiro Isobe, Chiba-shi (JP)

(73) Assignee: CANON KABUSHIKI KAISHA, Tokyo (JP)

(21) Appl. No.: 12/868,947

(22) Filed: Aug. 26, 2010

(30) Foreign Application Priority Data
Sep. 29, 2009 (JP) 2009-224327

(51) Int. Cl. G02F 1/1335; H01J 1/02; H01L 27/32

(52) U.S. Cl. 349/117; 313/112; 313/504

(57) ABSTRACT

A driving circuit of a liquid crystal element is simplified, both an improvement in light emission efficiency and a reduction in external light reflection are attained, and a cost reduction is realized.

### BACKGROUND OF THE INVENTION

1. Field of the Invention

The present invention relates to an image display apparatus, and relates, in particular, to a light emitting image display apparatus, such as an organic EL display apparatus, having a reflection electrode.

2. Description of the Related Art

In recent years, an organic EL display using an organic electroluminescence element (hereinafter, called “organic EL element”) is focusing attention. In a typical organic EL element, an organic layer including a light emission layer with about several hundred nm thickness is placed between a reflection electrode and a light transmitting electrode. In such a configuration of element, the reflection electrode reflects light (external light) incident from an outside into the element regardless of light emission by the element. Therefore, under the environment with intense external light, external light reflection components are greater than light emission components of the element. This leads to a decrease in the contrast of the organic EL display, and the visibility is degraded.

To solve such a problem, a circular polarizing unit is arranged on the organic EL element in a typical known technique. For example, a technique related to a circular polarizing plate including a linear polarization plate and a (¼)λ wavelength plate (including a plurality of birefringent plates) is disclosed (see Japanese Patent Application Laid-Open No. H09-127885).

When the circular polarizing plate is arranged on the organic EL element, the external light becomes clockwise or counterclockwise circularly polarized light and enters the organic EL element. The incident light is reflected after the reflection electrode of the organic EL element circularly polarizes the incident light in the opposite direction from the direction when the light has entered. When the light enters again in the circular polarizing plate, the light becomes linearly polarized light orthogonal to the axis of the linear polarization plate after passing through the (¼)λ wavelength plate and enters the linear polarization plate. Therefore, the light is shielded by the linear polarization plate. The effect significantly reduces the external light reflection.

However, the configuration has a problem that the light emission of the organic EL element is also reduced by the circular polarizing plate. This is caused by the linear polarization plate used as a constituent element of the circular polarizing plate, and the linear polarization plate cuts about 50% of the light.

To solve such a problem, in place of the linear polarization plate used as a constituent element of the circular polarizing plate, a configuration using a liquid crystal element having a nematic liquid crystal provided with a two-color pigment between substrates subjected to a uniaxial orientation process is proposed (see Japanese Patent Application Laid-Open No. 2000-113988). In the technique described in Japanese Patent Application Laid-Open No. 2000-113988, the external light reflection at a non-light emission part of the organic EL element is shut off by the effects of a liquid crystal element without application of voltage and of a (¼)λ wavelength plate. On the other hand, at a light emission part of the organic EL element, a voltage is applied to the liquid crystal element to control absorption of light in a liquid crystal layer, and the light emission of the organic EL element can be extracted to the outside without loss.

However, in the technique disclosed in Japanese Patent Application Laid-Open No. 2000-113988, the liquid crystal element needs to be driven in accordance with the non-light emission part and the light emission part of the organic EL element. Therefore, the liquid crystal element needs to be arranged in accordance with the arrangement pattern of the organic EL element. For example, if the organic EL element is arranged in a matrix, the liquid crystal element also needs to be driven in a matrix arrangement. In that case, not only the organic EL element, but also the driving circuit of the liquid crystal element becomes complicated, and the cost of the display may be high.

### SUMMARY OF THE INVENTION

The present invention has been proposed in view of the foregoing circumstances, and an object of the present invention is to provide an image display apparatus capable of simplifying a driving circuit of a liquid crystal element, attaining both an improvement in light emission efficiency and a reduction in external light reflection, and realizing a cost reduction.

An image display apparatus according to the present invention comprises: a display panel having a light emitting element; a circular polarizing element having a retardation plate and an optical element having a controllable liner polarizing function, and being placed on a light emission side of the display panel such that the display panel, the retardation plate and the optical element are placed in this order, wherein the controllable liner polarizing function of the optical element in a light emission period of the light emitting element is different from that in a non-light emission period of the light emitting element.

According to the image display apparatus of the present invention, the optical element is driven in synchronous with the light emission period and the non-light emission period within one frame of the light emitting element. At this point, if the whole area of the image display apparatus simultaneously performs light emission period/non-light emission period in the drive method, the driving circuit of the liquid crystal element can be simplified because the liquid crystal element can also be driven all together throughout the whole area. Therefore, both an improvement in light emission efficiency of the image display apparatus and a reduction in external light reflection can be attained, and the functions can be realized with low cost.

Further features of the present invention will become apparent from the following description of exemplary embodiments with reference to the attached drawings.

### BRIEF DESCRIPTION OF THE DRAWINGS

FIG. 1 is a schematic overall diagram illustrating an example of an image display apparatus according to embodiments of the present invention.

FIG. 2 is a schematic diagram illustrating an example of an organic EL panel according to the embodiments of the present invention.

FIG. 3 is a schematic enlarged cross-sectional view illustrating an example of the organic EL element according to the embodiments of the present invention.

FIG. 4 is a schematic diagram illustrating an example of a variable circular polarizing unit used in the image display apparatus according to the embodiments of the present invention.

FIGS. 5A, 5B and 5C are timing charts describing operations of the organic EL panel and the variable circular polarizing unit according to the embodiments of the present invention.

FIG. 6 is an example of configuration of a pixel circuit including the organic EL element according to the embodiments of the present invention.

FIG. 7 is a timing chart of signal lines of a first row, an n-th row, and an N-th row according to a first embodiment of the present invention.

FIG. 8 is a timing chart of signal lines of a first row, an n-th row, and an N-th row according to a second embodiment of the present invention.

FIGS. 9A and 9B are schematic diagrams illustrating an example of the variable circular polarizing unit used in the image display apparatus according to the embodiments of the present invention.

FIG. 10 is a timing chart of signal lines of a first row, a second row, a (2n-1)-th row, and a (2n)-th row according to a third embodiment of the present invention.

### DESCRIPTION OF THE EMBODIMENTS

Embodiments of an image display apparatus of the present invention will be described with reference to the drawings.

<Schematic Configuration>

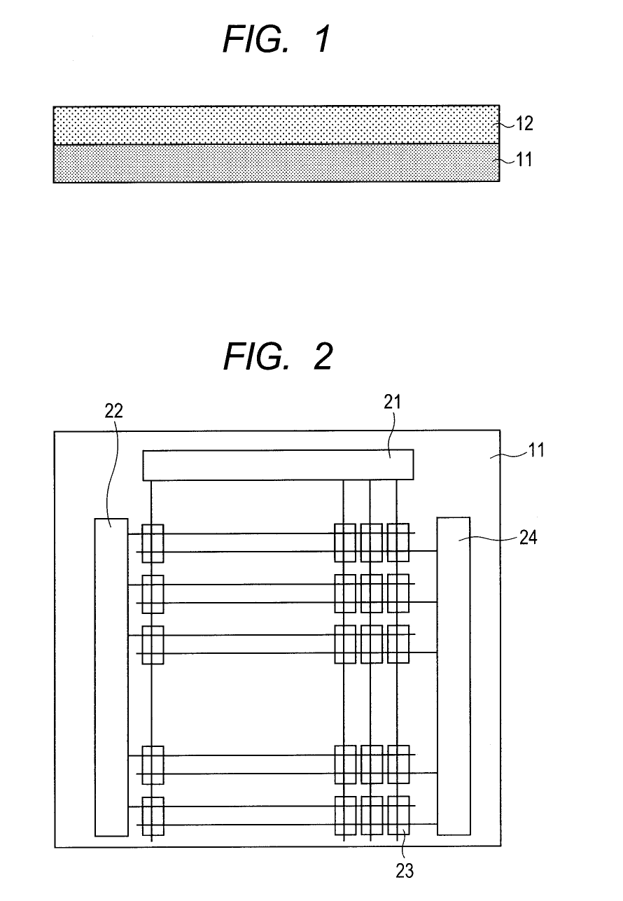

FIG. 1 is a schematic overall diagram illustrating an example of an image display apparatus according to embodiments of the present invention.

The image display apparatus according to the embodiments of the present invention comprises a display panel having a light emitting element having a reflection electrode. The image display apparatus also comprises a circular polarizing unit including: a retardation plate; and an optical element having a linear polarization function, on a light emission side of the light emitting element in this order from a light emitting element side. Specifically, as illustrated in FIG. 1, a variable circular polarizing unit 12 is arranged on top of a light emitting surface side of an organic EL panel 11.

As described in detail later, the organic EL panel 11 is equivalent to the display panel, and a positive electrode 32 of the organic EL panel 11 is equivalent to the reflection electrode. The variable circular polarizing unit 12 is equivalent to the circular polarizing unit, a (¼)λ wavelength plate 41 constituting the variable circular polarizing unit 12 is equivalent to the retardation plate, and a liquid crystal element 42 is equivalent to the optical element (see FIGS. 1 and 4).

In the present invention, the light emitting element is configured to synchronize with the light emission period within one frame to weaken the linear polarization function of the optical element, and the light emitting element is configured to synchronize with the non-light emission period within one frame to intensify the linear polarization function of the optical element. When the linear polarization function is weakened, the light reflected from the reflection electrode is easily shielded. On the other hand, when the linear polarization function is intensified, the light reflected from the reflection electrode is not easily shielded and is easily transmitted. A plurality of light emitting elements are arranged on the display panel, and the display panel comprises a controlling unit that sets the plurality of light emitting elements to a light emitting state or a non-light emitting state all together. In that case, the optical element in the circular polarizing unit can be one liquid crystal element corresponding to the whole area of the plurality of light emitting elements.

A plurality of light emitting elements may be arranged in a matrix in the display panel, and the display panel may comprise a controlling unit that sets one row or an arbitrary number of rows of the light emitting elements to a light emitting state or a non-light emitting state. In that case, the optical element in the circular polarizing unit may be a plurality of liquid crystal elements corresponding to the whole area of the light emitting elements in the arbitrary number of rows.

The light emitting element can be an organic electroluminescence element.

<Organic EL Panel>

The organic EL panel 11 will be described first.

FIG. 2 is a schematic diagram illustrating an example of an organic EL panel according to the embodiments of the present invention.

As illustrated in FIG. 2, the organic EL panel 11 includes a signal line driving circuit 21 that applies a signal voltage corresponding to image information to a signal line, a scanning line driving circuit 22 that drives a scanning line, a pixel circuit 23 that controls an electric current applied to pixels in accordance with a signal voltage value, and a light emission period control line driving circuit 24 that controls the light emission period. The light emission period control line driving circuit and a light emission period control line correspond to the controlling unit that sets the light emitting state and the non-light emitting state.

<Organic EL Element>

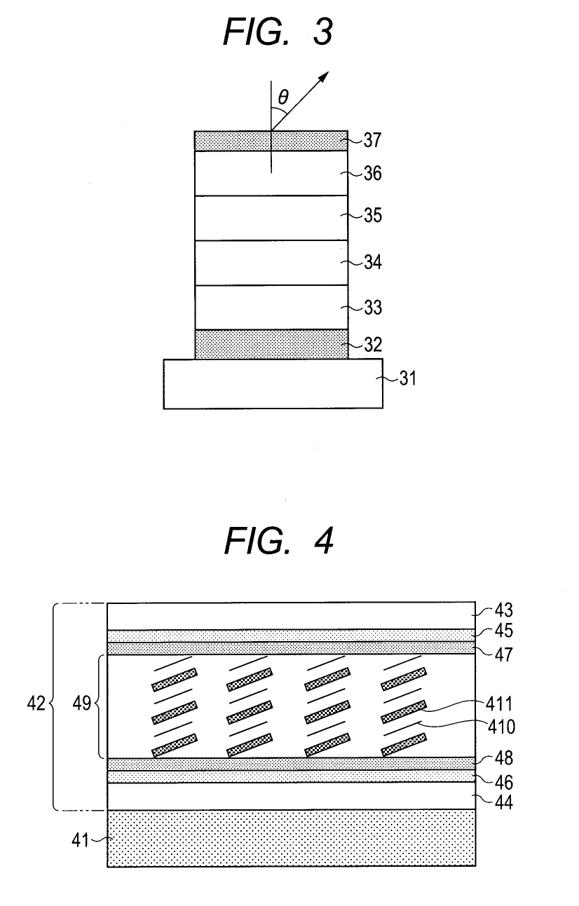

FIG. 3 is a schematic enlarged cross-sectional view illustrating an example of an organic EL element that is a typical light emitting element of an organic EL panel.

In the organic EL element, a positive electrode (reflection electrode) 32, a hole transporting layer 33, a light emission layer 34, an electron transporting layer 35, an electron injection layer 36, and a negative electrode (half-light transmitting electrode) 37 are sequentially arranged on a substrate 31. When an electric current is applied to the organic EL element, holes injected from the positive electrode 32 and electrons injected from the negative electrode 37 recombine in the light emission layer 34, and light is emitted. The layers of the hole transporting layer 33, the light emission layer 34, the electron transporting layer 35, and the electron injection layer 36 will be called organic compound layers.

Although an example of a configuration of forming the positive electrode 32 on the substrate 31 is illustrated in the embodiments, the negative electrode (reflection electrode) 37, the organic compound layers, and the positive electrode (half-light transmitting electrode) 32 may be arranged on the substrate 31 in this order. The selection of electrodes and the order of lamination of the layers are not particularly limited. Although the embodiments illustrate a top-emission type display apparatus in which the light emission is extracted from the half-light transmitting electrode 37 on the opposite side of the substrate 31, the present invention can also be applied to a bottom-emission type display apparatus.

Organic compound materials used for the hole transporting layer 33, the light emission layer 34, the electron transporting layer 35, and the electron injection layer 36 may include low-molecular materials, high-molecular materials, or both. The organic compound materials are not particularly limited, and known materials can be used as necessary. The organic EL element needs to be protected from the outside air such as moisture. Therefore, for example, the organic EL element may be placed between glasses or may be protected by an inorganic film, and the method is not particularly limited.

Although the device configuration of the organic EL panel 11 has been described, the organic EL panel 11 may be an organic EL panel including organic EL elements of R, G, and B three colors or including color filters arranged on top of a white organic EL element. Although the organic EL element has been described as the light emitting element, any element may be applied as long as the element is a light emitting element including a reflection electrode.

<Variable Circular Polarizing Unit>

The variable circular polarizing unit 12 will be described. FIG. 4 illustrates a schematic diagram of a variable circular polarizing unit.

As illustrated in FIG. 4, the variable circular polarizing unit 12 includes the (¼)λ wavelength plate 41 and the liquid crystal element 42. In the liquid crystal element 42, light transmitting electrodes 45 and 46 and oriented films 47 and 48 are formed on glass substrates 43 and 44, and a liquid crystal 49 is placed between the glass substrates 43 and 44. The liquid crystal 49 is a guest host liquid crystal in which a nematic liquid crystal 410 and a two-color pigment 411 are mixed, and the liquid crystal 49 indicates positive dielectric anisotrophy. A uniaxial orientation process is applied to the oriented films 47 and 48. In that case, liquid crystal molecules are horizontally oriented when a voltage is not applied to the liquid crystal 49, i.e. when the linear polarization function is weakened. The liquid crystal molecules are vertically orientated when a voltage is applied to the liquid crystal 49, i.e. when the linear polarization function is intensified. The optical axis of the (¼)λ wavelength plate 41 is arranged to form a 45 degree angle with the orientation axis of the liquid crystal element 42.

The nematic liquid crystal 410 is substantially horizontally oriented along the glass substrates 43 and 44 in accordance with the oriented film when a voltage is not applied to the liquid crystal element 42. In this case, the major axis direction of the two-color pigment 411 is also arranged in the same way in accordance with the nematic liquid crystal 410. Therefore, in this state, one direction of the light entering the liquid crystal element 42 is absorbed by the two-color pigment 411. As a result, the liquid crystal element 42 functions as a linear polarization plate.

In this way, the liquid crystal element 42 functioning as a linear polarization plate and the (¼)λ wavelength plate 41 are combined, and the variable circular polarizing unit 12 functions as a circular polarizing plate. Therefore, in this case, the external light reflection is reduced, and the transmittance of the emitted light is approximately halved.

On the other hand, the nematic liquid crystal 410 is vertically oriented relative to the glass substrates 43 and 44 when a voltage is applied to the liquid crystal element 42. In this case, the major axis direction of the two-color pigment 411 is also arranged in the same way in accordance with the nematic liquid crystal 410. Therefore, in this state, the light entering the liquid crystal element 42 is transmitted without being absorbed by the two-color pigment 411.

Therefore, the liquid crystal element 42 does not function as a linear polarization plate, and the transmittance of the emitted light is still high even if the liquid crystal element 42 is combined with the (¼)λ wavelength plate 41. More specifically, the external light reflection of the variable circular polarizing unit 12 is larger when a voltage is applied, compared to when a voltage is not applied. However, the transmittance of the emitted light is high, and the transmittance of the emitted light is higher than that in a normal circular polarizing plate.

The foregoing is an example of a liquid crystal element using a nematic liquid crystal. In an application requiring high speed response during ON/OFF of the electric field, the nematic liquid crystal may not be used because the response speed is slow. Republished Patent Application No. WO2005/090520 discloses a high-molecular stabilized blue phase liquid crystal and describes that the response time is about 100 μsec.

<High Speed Response Element>

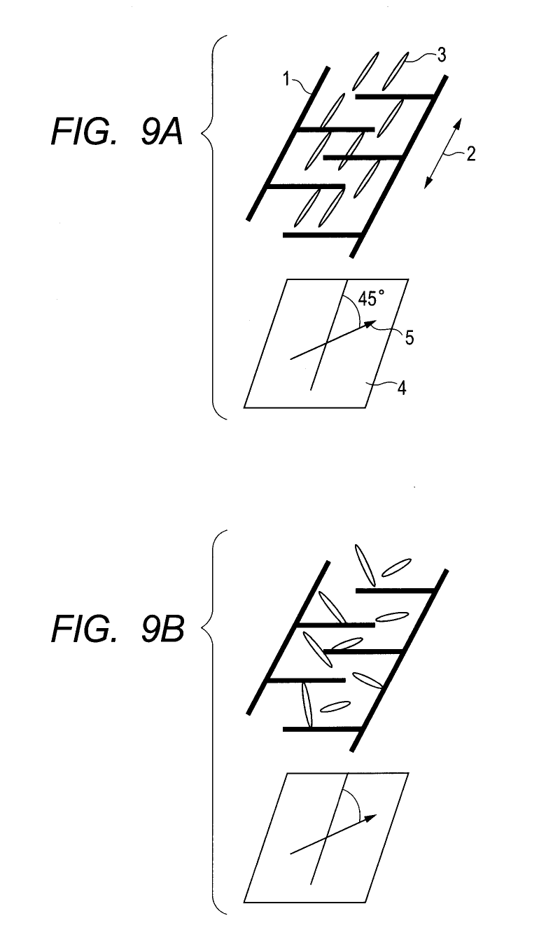

FIGS. 9A and 9B illustrate a structure of a high speed response element as an example of a variable circular polarizing unit used in the image display apparatus according to the embodiments of the present invention.

As illustrated in FIGS. 9A and 9B, in the high speed response element, a comb-shaped electrode 1 is arranged on a substrate (not shown), such as a glass, within the same plane, and an electric field 2 is applied in parallel to a substrate surface. The other substrate is sandwiched by glass plates without electrode through a spacer, and a high-molecular stabilized blue liquid crystal material (liquid crystal 3) is injected to the generated gap.

As illustrated in FIG. 9A, the liquid crystal 3 is oriented in the direction of the electric field when a voltage is applied to the comb-shaped electrode 1. Uniaxial refractive index anisotrophy is generated, and the high speed response element functions as a linear polarization plate. A function as a circular polarizing plate is generated by combining the high speed response element with the (¼)λ wavelength plate 4 having a 45 degree optical axis 5.

Meanwhile, as illustrated in FIG. 9B, the liquid crystal 3 is randomly oriented when the electric field is turned off. The function of the circular polarizing plate disappears, and light can be transmitted.

<Synchronization Operation of Variable Circular Polarizing Unit>

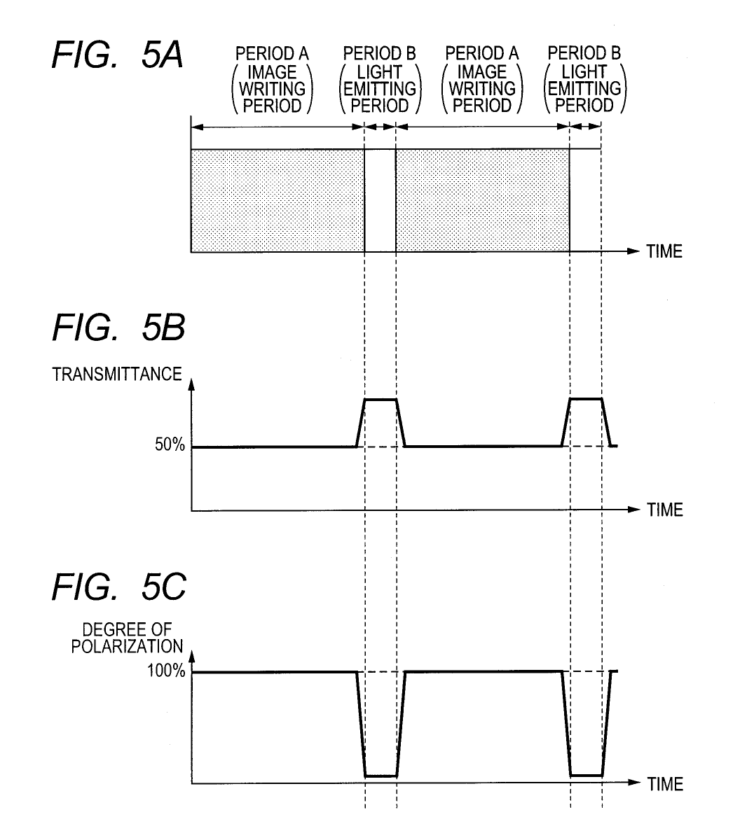

A synchronization operation of the organic EL panel 11 and the variable circular polarizing unit 12 will be described with reference to FIGS. 5A to 5C. FIGS. 5A to 5C are timing charts describing an operation of an organic EL panel and a variable circular polarizing unit.

FIG. 5A illustrates a drive sequence of the organic EL panel 11. As illustrated in FIG. 5A, the scanning line driving circuit 22 that drives a scanning line sequentially writes signal voltages corresponding to image information to the pixel circuit 23 in a period A. It is desirable to light up the whole area all together in a period B after the signal voltages are written to all pixels. A combination of one period A (writing period of signal voltage) and one period B (period that the light emitting element emits light) will be called one frame.

FIGS. 5B and 5C illustrate sequences of transmittance and polarization of the variable circular polarizing unit 12, respectively.

As illustrated in FIGS. 5B and 5C, a voltage is not applied to the liquid crystal element 42 in the period A, and the variable circular polarizing unit 12 functions as a circular polarizing plate. The operation reduces the external light reflection in the period A. In this case, since the organic EL panel 11 does not emit light, the light emission is not lost.

A voltage is applied to the liquid crystal element 42 in the period B to increase the transmittance of the emitted light in the variable circular polarizing unit 12. As a result of the operation, the light emission of the organic EL panel 11 can be efficiently extracted in the period B, compared to a normal circular polarizing plate. Since the variable circular polarizing unit 12 does not function as a circular polarizing plate in the period B, the external light reflection increases.

More specifically, the direction of orientation of the liquid crystal element is controlled so that the ratio of light emitted from the light emitting element transmitting through the retardation plate and the liquid crystal element is larger in the light emission period within one frame in the drive of the light emitting element than in the non-light emission period.

Therefore, the amount of external light reflection varies depending on the ratio of the period A and the period B. The amount of external light refection can be reduced when the period of lighting up in the whole area is shorter, and the visibility improves.

The image display apparatus of the present invention will be described in further detail based on specific embodiments.

### First Embodiment

A schematic configuration of the image display apparatus of a first embodiment is the same as the configuration illustrated in FIG. 1. A summary of the organic EL panel of the first embodiment is the same as the summary illustrated in FIG. 2.

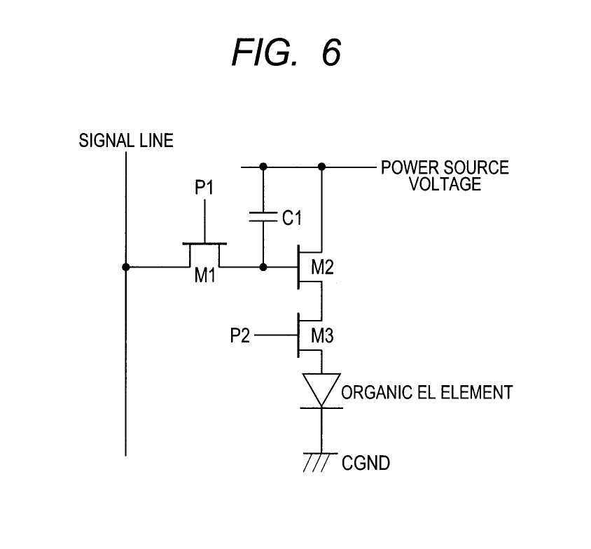

FIG. 6 illustrates an example of configuration of a pixel circuit including an organic EL element of the first embodiment.

In FIG. 6, P1 denotes a scanning line, and P2 denotes a light emission period control line. A signal voltage is input from the signal line in accordance with image information. A positive electrode of the organic EL element is connected to a drain terminal of a TFT (M3), and a negative electrode is connected to a ground potential CGND. Hereinafter, a brief operation of the pixel circuit will be described.

When the signal voltage is written, a signal of HI level is input to the scan signal P1, and a signal of LOW level is input to P2. A transistor M1 is ON, and M3 is OFF. At this point, M3 is not conductive, and an electric current does not flow through the organic EL element. Based on the signal voltage, a voltage corresponding to the electric current drive capability of M1 is generated in a capacity C1 arranged between a gate terminal of M2 and a power potential V1.

A signal of LOW level is input to P1, and a signal of LOW level is input to P2 to shut off the electric current flowing through the organic EL element while maintaining the written signal voltage. At this point, the transistors M1 and M3 are OFF. Since M3 is not conductive, the supply of electric current to the organic EL element can be shut off, and a non-light emitting state can be set.

A signal of LOW level is input to P1, and a signal of HI level is input to P2 to supply an electric current to the organic EL element in accordance with the maintenance of the written signal voltage. At this point, the transistor M1 is OFF, and M3 is ON. Since M3 is conductive, an electric current corresponding to the electric current drive capability of M2 is supplied to the organic EL element based on the voltage generated in C1, and the organic EL element emits light with luminance corresponding to the supplied electric current.

In this way, switching HI/LOW of the signal level input to P2 can arbitrarily control the light emission period.

Although the configuration of FIG. 2 is implemented for the pixel circuit in the first embodiment, the pixel circuit is not limited to this. Any configuration can be implemented as long as the drive system/pixel circuit can control the light emission period.

An operation of the entire organic EL panel will be described.

In the organic EL panel of the first embodiment, signal voltages corresponding to image information that the pixels should display are simultaneously written to the pixels of the pixel group connected to one scanning line during one horizontal period. Similarly, signal voltages are sequentially written to pixel groups connected to scanning lines of the following rows. Writing to all pixels is finished within a period shorter than one vertical period. For example, one vertical period is 16.67 [msec] in the case of an organic EL panel at 60 Hz drive. The organic EL panel of the first embodiment has a matrix arrangement of N rows and M columns. The scanning line P1 connected to the pixel circuit of an n-th row of the organic EL panel is designated with P1n, and a light emission period control line is designated with P2n (N, n, and M are natural numbers, 1≦n≦N).

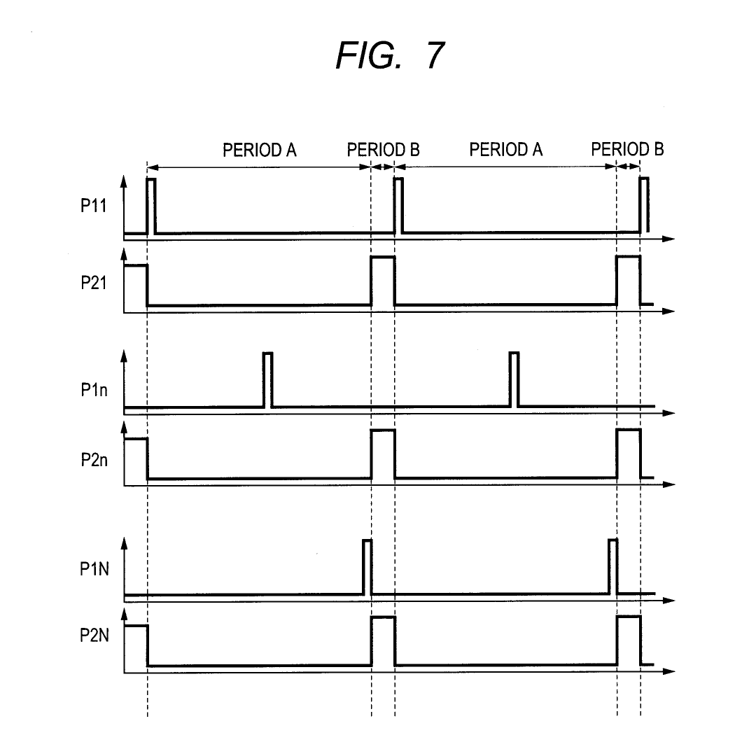

FIG. 7 illustrates a timing chart of scanning lines of a first row, an n-th row, and an N-th row according to the first embodiment.

<Period A/Writing Period of Signal Voltage>

Writing to the n-th row of the organic EL panel is performed when P1n is HI and P2n is LOW, and the image information is stored in the pixel circuit in accordance with the signal voltage input from the signal line. Subsequently, P1n becomes LOW and P2n becomes LOW, and an electric current can be applied to the organic EL element in accordance with the stored information. However, a transistor M3 is turned off because P2n is LOW, and the electric current does not flow through the organic EL element. In this state, writing to the next row (n+1) is performed, and writing from the first row to the N-th row is finished without applying the electric current to the organic EL element. The period A is 15.00 [msec] here, and writing of the signal voltages corresponding to the image information to all pixel circuits is finished within the period. The organic EL element does not emit light in the period.

<Period B/Period that All Pixels Emit Light>

When writing of the signal voltages to all pixels is finished in the period A, all pixels emit light all together. For example, in the pixels of the n row of the organic EL panel, P1n is set to LOW, and P2n is set to HI (transistor M3 is ON). An electric current flows through the organic EL element in accordance with the signal voltages stored in the pixel circuits, and the organic EL element emits light. The period B is 1.67 msec here, and the organic EL element emits light only in the period.

<Variable Circular Polarizing Unit>

The variable circular polarizing unit 12 will be described.

The light transmitting electrodes 45 and 46 arranged on the glass substrates 43 and 44 of the liquid crystal element 42 are formed all together throughout the whole area of the region corresponding to the organic EL panel. Therefore, the linear polarization function can be adjusted all together throughout the whole area in the liquid crystal element 42.

In the period A, a voltage is not applied to the liquid crystal element 42 of the variable circular polarizing unit 12, and the variable circular polarizing unit 12 functions as a circular polarizing plate. The operation reduces the external light reflection in the period A. The period A is a non-light emission period in which the organic EL panel 11 does not emit light, and the light emission is not lost.

A voltage is applied to the liquid crystal element 42 of the variable circular polarizing unit 12 in the period B to increase the transmittance of the variable circular polarizing unit 12. As a result of the operation, the light emission of the organic EL panel 11 can be more efficiently extracted in the period B, compared to a normal circular polarizing plate. The period B is a light emission period.

Therefore, the first embodiment can provide an organic EL panel with excellent extraction efficiency of emitted light, compared to when a typical circular polarizing plate is used. Simply put, a display with about twice the luminance as that of a conventional display can be provided. The power consumption can be approximately halved when compared under the same luminance.

As for the external light reflection, a similar effect as the circular polarizing plate can be obtained in the period A. Although the amount of the external light reflection increases in the period B, the time of the period B is about 1/10 of that of the period A. Therefore, as for the external light reflection, excellent visibility close to when the circular polarizing plate is used can be obtained.

The effect of the circular polarizing plate increases if the period B is less than ⅕ of the period A. The period B can be less than 1/10 of the period A, and it is optimal that the period B is less than 1/20 of the period A. Meanwhile, the period B is short if the period B is less than 1/30 of the period A, and the lifetime of the organic EL panel becomes short. Therefore, it is desirable that the period B is equal to or greater than 1/30 of the period A.

The light transmitting electrodes 45 and 46 formed on the liquid crystal element 42 may be formed all together throughout the whole area of the region corresponding to liquid crystal element 42, and the drive system of the liquid crystal element 42 may be simple. Therefore, the variable circular polarizing unit can be inexpensively provided.

### Second Embodiment

In the first embodiment, the light emission period and the non-light emission period of the organic EL panel 11 are controlled all together throughout all pixels, and the drive of the variable circular polarizing unit 12 is controlled all together throughout the whole area. In a second embodiment, the periods and the drive are controlled row by row.

The configuration of a pixel circuit of the second embodiment including an image display apparatus, an organic EL panel, and an organic EL element is the same as the configuration of the first embodiment.

An operation of the entire organic EL panel will be described.

As in the first embodiment, the organic EL panel of the second embodiment has a matrix arrangement of N rows and M columns. The scanning line P1 connected to the pixel circuit of an n-th row of the organic EL panel is designated with P1n, and the light emission period control line is designated with P2n (N, n, M, and m are natural numbers, 1≦n≦N).

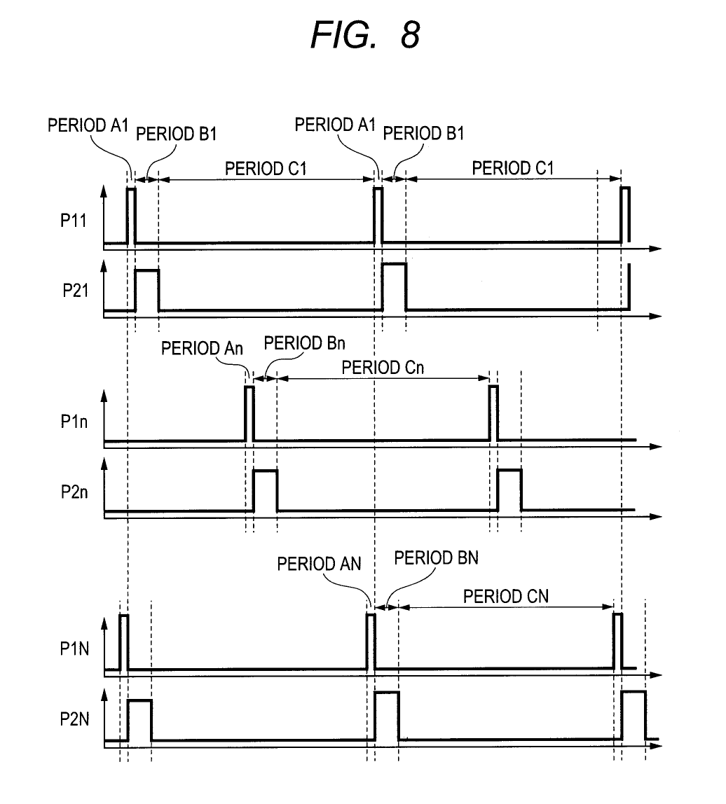

FIG. 8 illustrates a timing chart of signal lines of a first row, an n-th row, and an N-th row according to the second embodiment.

<Period An/Writing Period of Signal Voltage>

Writing to the n row of the organic EL panel is performed when P1n is HI and P2n is LOW, and information is stored in the pixel circuit in accordance with signal voltages input from the signal lines. The time of a period An is (16.67/N(msec)) here, and writing of a signal voltage to the pixel circuit of the n-th row is finished within the period. The organic EL element does not emit light in the period. After the operation, a writing operation to the next row starts.

<Period Bn/Period that Organic EL Element Emits Light>

After the period An, P1n is LOW and P2n is HI in the control signal for the n-th row of the organic EL panel. The transistor M3 turns on, and an electric current flows through the organic EL element in accordance with the image information stored in the pixel circuit. As a result, the organic EL element emits light with brightness corresponding to the image information.

<Period Cn/Period that Organic EL Element Does Not Emit Light>

After the period Bn, P1n is LOW and P2n is LOW in the control signal for the n-th row of the organic EL panel. Although the image information is already stored in the pixel circuit, the transistor M3 is OFF, and an electric current does not flow through the organic EL current. Therefore, the organic EL element does not emit light.

In other words, the periods An and Cn are non-light emission periods in which the organic EL element does not emit light, and the period Bn is a light emission period in which the organic EL element emits light.

<Variable Circular Polarizing Unit>

The variable circular polarizing unit 12 will be described.

One of the light transmitting electrodes 45 and 46 included in the glass substrates 43 and 44 of the liquid crystal element 42 is formed all together throughout the whole area of the region corresponding to the organic EL panel, and the other is patterned with stripes according to the row direction of the organic EL panel 11. As a result, the liquid crystal element 42 can adjust the linear polarization function row by row.

In the periods An and Cn, a voltage is not applied to the liquid crystal element 42 of the variable circular polarizing unit 12, and the variable circular polarizing unit 12 functions as a circular polarizing plate. The operation reduces the external light refection in the periods An and Cn. At this point, the organic EL panel 11 does not emit light, and the light emission is not lost.

In the period Bn, a voltage is applied to the liquid crystal element 42 of the variable circular polarizing unit 12 to increase the transmittance of the variable circular polarizing unit 12. As a result of the operation, the light emission of the organic EL panel 11 can be efficiently extracted in the period Bn, compared to a normal circular polarizing plate.

Therefore, as in the first embodiment, an organic EL panel with excellent extraction efficiency of emitted light can be provided, compared to when a typical circular polarizing plate is used. As for the external light reflection, excellent visibility close to when the circular polarizing plate is used can be obtained.

The light transmitting electrode formed on the liquid crystal element 42 may be patterned with lines corresponding to the row layout of the panel, and the drive system of the liquid crystal element 42 may also be simple. Therefore, the variable circular polarizing unit can be inexpensively provided.

### Third Embodiment

In the second embodiment, the light emission period and the non-light emission period of the organic EL panel 11 are controlled row by row, and the drive of the variable circular polarizing unit 12 is also controlled in accordance with the row-by-row control of the organic EL panel 11. In a third embodiment, the periods and the drive are controlled by an arbitrary number of rows. An example of a configuration of controlling two rows by two rows will be illustrated below.

A configuration of a pixel circuit including an image display apparatus, an organic EL panel, and an organic EL element of the third embodiment is the same as that of the first embodiment.

An operation of the entire organic EL panel will be described.

As in the first embodiment, the organic EL panel of the third embodiment has a matrix arrangement of N rows and M columns, the scanning line P1 connected to the pixel circuit of an n-th row of the organic EL panel is designated with P1n, and the light emission period control line is designated with P2n (N, n, M, and m are natural numbers, 1≦n≦N).

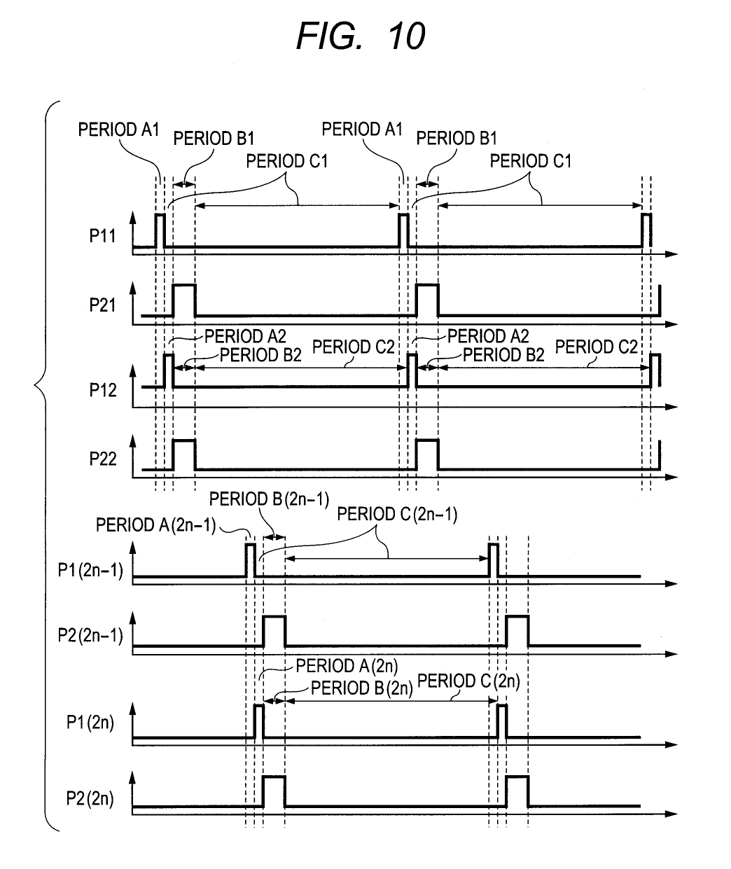

FIG. 10 illustrates a timing chart of signal lines of a first row, a second row, a (2n-1)-th row, and a (2n)-th row according to the third embodiment. The control of light emission of the organic EL panel two rows by two rows will be described, and an operation of a k-th row (k is a natural number) will be described.

<Period Ak/Writing Period of Signal Voltage>

Writing to the k-th row of the organic EL panel is performed when P1k is HI and P2k is LOW, and information is stored in the pixel circuit in accordance with the signal voltages input from the signal lines. The time of the period Ak is (16.67/N[msec]) here, and writing of the signal voltages to the pixel circuit of the k-th row is finished within the period. The organic EL element does not emit light in the period. After the operation, a writing operation of the next row starts.

<Period Bk/Period that Organic EL Element Emits Light>

In the control signal for the k-th row of the organic EL panel, P1k is LOW, and P2k is HI. The transistor M3 turns on, and an electric current flows through the organic EL element in accordance with the image information stored in the pixel circuit. As a result, the organic EL element emits light with brightness corresponding to the image information.

<Period Ck/Period that Organic EL Element Does Not Emit Light>

In the control signal for the k-th row of the organic EL panel, P1k is LOW, and P2k is LOW. Although the image information is already stored in the pixel circuit, the transistor M3 is turned off, and the electric current does not flow through the organic EL element. Therefore, the organic EL element does not emit light.

In other words, the periods An and Cn are non-light emission periods in which the organic EL element does not emit light, and the period Bn is a light emission period in which the organic EL element emits light.

As illustrated in FIG. 10, light emission period control signals P2(2n-1) and P2(2n) input to adjacent (2n-1)-th row and (2n)-th row are the same in order to make the timing of the light emission periods (period B) of the organic EL element of the (2n-1)-th row and the (2n)-th row the same. As a result, the light emission is controlled two rows by two rows.

Although the two-row-by-two-row control of the light emission period and the non-light emission period of the organic EL panel has been described, the number of rows is not limited to this. More specifically, the number of lit rows can be arbitrarily set if the same light emission period control signal P2 is input to the arbitrary number of rows.

<Variable Circular Polarizing Unit>

The variable circular polarizing unit 12 will be described.

One of the light transmitting electrodes 45 and 46 included in the glass substrates 43 and 44 of the liquid crystal element 42 is formed all together throughout the whole area corresponding to the organic EL panel, and the other is patterned with stripes in accordance with the arbitrary number of rows for emitting light at the same timing of the organic EL panel 11. Therefore, the liquid crystal element 42 can adjust the linear polarization function in accordance with each light emission region and each timing of the organic EL panel 11.

The operation of the variable circular polarizing unit 12 is the same as that of the second embodiment.

Therefore, as in the first embodiment, an organic EL panel with excellent extraction efficiency of emitted light can be provided, compared to when a typical circular polarizing plate is used. As for the external light reflection, excellent visibility close to when the circular polarizing plate is used can be obtained.

The light transmitting electrode formed on the liquid crystal element 42 may be patterned with lines corresponding to the row layout of the organic EL panel, and the drive system of the liquid crystal element 42 may also be simple. Therefore, the variable circular polarizing unit can be inexpensively provided.

### Fourth Embodiment

In a fourth embodiment, the above-mentioned high-molecular stabilized blue phase liquid crystal is used for the liquid crystal element of the variable circular polarizing unit 12. Other content, operations, and effects are the same as those of the first and second embodiments.

The material disclosed in the above-mentioned document (Republished Patent Application No. WO2005/090520) is used and injected to a cell forming the comb-shaped electrode, and a phase forming plate is further attached to create the high speed response element using the high-molecular stabilized phase liquid crystal.

Although the optical element that controls the linear polarization of the variable circular polarizing unit 12 is a liquid crystal element in the description, the element is not limited to this.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-224327, filed on Sep. 29, 2009, which is hereby incorporated by reference herein in its entirety.

What is claimed is:

1. An image display apparatus comprising:
a display panel having a light emitting element;
a circular polarizing element having a retardation plate and an optical element having a controllable liner polarizing function, and being placed on a light emission side of the display panel such that the display panel, the retardation plate and the optical element are placed in this order, wherein
the controllable liner polarizing function of the optical element in a light emission period of the light emitting element is different from that in a non-light emission period of the light emitting element.

2. The image display apparatus according to claim 1, wherein
the liner polarizing function of the optical element in the light emission period is intensified rather than that in the non-light emission period of the light emitting element.

3. The image display apparatus according to claim 1, wherein
the light emission period of the light emitting element is 1/30-⅕ of the non-light emission period of the light emitting element.

4. The image display apparatus according to claim 1, wherein
the display panel has a plurality of the light emitting elements, and further has a control unit capable of setting, at a light emitting state or at a non-light emitting state, all of the light emitting elements together and wherein
the optical element comprises a single liquid crystal element corresponding to a whole area in which all of the light emitting elements are arranged.

5. The image display apparatus according to claim 1, wherein
the display panel has a plurality of the light emitting elements arranged in a matrix, and further has a control unit capable of setting, at a light emitting state or at a non-light emitting state, an arbitrary number of rows of the light emitting elements, and wherein
the optical element comprises a plurality of liquid crystal elements of which number corresponds to a total number of the light emitting elements in the arbitrary number of rows.

6. The image display apparatus according to claim 1, wherein
the light emitting element is an organic electroluminescence element.

7. The image display apparatus according to claim 1, wherein
the light emitting element includes an electrode reflecting an externally incident light.

8. An image display apparatus comprising:
a display panel having a light emitting element;
a retardation plate and a liquid crystal element, being placed on a light emission side of the display panel such that the display panel, the retardation plate and the liquid crystal element are placed in this order, wherein
a ratio of light transmitting through the retardation plate and the liquid crystal element in a light emitting period within one frame of driving the light emitting element is larger than that in a non-light emitting period within one frame of driving the light emitting element.
